(19) United States
(12) Patent Application Publication
(10) Pub. No.: US 2025/0366280 A1
(43) Pub. Date: Nov. 27, 2025

(54) SEMICONDUCTOR DEVICE AND METHOD FOR FORMING THE SAME

(71) Applicant: TAIWAN SEMICONDUCTOR MANUFACTURING COMPANY LTD., HSINCHU (TW)

(72) Inventors: YI-FONG LAI, CHANGHUA COUNTY (TW); CHUNG-CHUAN TSENG, HSINCHU CITY (TW); PO-YU CHEN, HSINCHU CITY (TW); LI-WEN HO, HSINCHU CITY (TW); YU-CHEN DENG, TAOYUAN CITY (TW)

(21) Appl. No.: 18/673,362

(22) Filed: May 24, 2024

(51) Int. Cl. H01L 33/62; H01L 21/67

(52) U.S. Cl. CPC H10H 20/857; H01L 21/67144; H10H 20/0364

(57) ABSTRACT

A semiconductor device includes a substrate, a dielectric layer over the substrate, a conductive feature over the dielectric layer and is physically connected to a connecting via embedded in the dielectric layer; and a plurality of dummy structures over the dielectric layer and surrounding the conductive feature. A top surface of the conductive feature is separate from top surfaces of the dummy structures, and the plurality of dummy structures are electrically connected to the conductive feature.

### BACKGROUND

“Mass transfer” refers to technologies for transferring millions of micro-LED chips formed on a temporary substrate to a final substrate for the final formation of displays, is an essential step for the assembly of micro-LEDs.

Mass transfer technologies include, for example, fluid assembly, laser transfer, roll-to-roll transfer, and stamp pick-and-place techniques, among stamp pick-and-place techniques are frequently used. During the mass transfer process by the pick-and-place technique, chips are picked from the temporary substrate and placed on to a final substrate by a transfer stamp (“pick head”). If the surface roughness of the chips is too high and the contact area between the chip and the pick head is too small, the chips will drop during the mass transfer process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of a semiconductor device in accordance with some embodiments of the present disclosure.

FIGS. 2A to 2D illustrate schematic top-views of a semiconductor device in accordance with some embodiments of the present disclosure.

FIGS. 3A and 3B illustrate schematic top-views of a semiconductor device in accordance with some embodiments of the present disclosure.

FIG. 4 illustrates a schematic cross-sectional view of a semiconductor device shown in FIG. 3A along line A-A′ in accordance with some embodiments of the present disclosure.

FIG. 5 illustrates a flowchart of a method for forming a semiconductor device in accordance with some embodiments of the present disclosure.

FIGS. 6A to 6F illustrate schematic cross-sectional views of a semiconductor device at various stages of fabrication in accordance with some embodiments of the present disclosure.

FIGS. 7A to 7E illustrate schematic cross-sectional views of a semiconductor device at various stages of fabrication in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

During the production of the micro-LEDs, massive micro-LED pixels were first grown on a wafer, and, prior to dicing micro-LEDs chips from the wafer, the wafer is thinned and adhered to a temporary substrate by an adhesive. The thinned wafer is then diced into massive micro-LED chips while being adhered to the temporary substrate. The micro-LED chips are then transferred from the temporary substrate to a final display substrate by a mass transfer process, such as “stamp pick-and-place” process, roll-printing process, self-assembly process, and selective release process, among which the “stamp pick-and-place” process is a widely used process.

During the mass transfer of the micro-LED chips from the temporary substrate to the final substrate by the stamp pick-and-place process, a pick head attaches to the contact pad patterns on the surface of the micro-LED chips and pick the micro-LED chips by the pick force, such as van der Waals force, between the contact pad patterns and the pick head. The pick force plays an important role in retaining the chip from being dropped from the pick head during transfer. Therefore, a micro-LED chip with a contact pad pattern contacting the pick head that improves the pick force between the pick head and the micro-LED chip is desired.

The present disclosure therefore provides a semiconductor device and a method for forming the same. In some embodiments, the semiconductor device may be a micro-LED chip. In some embodiments, the semiconductor device includes a pad pattern having a greater contact area with the pick head and a reduced surface roughness. Thus, the pick force between the semiconductor device and the pick head is further improved.

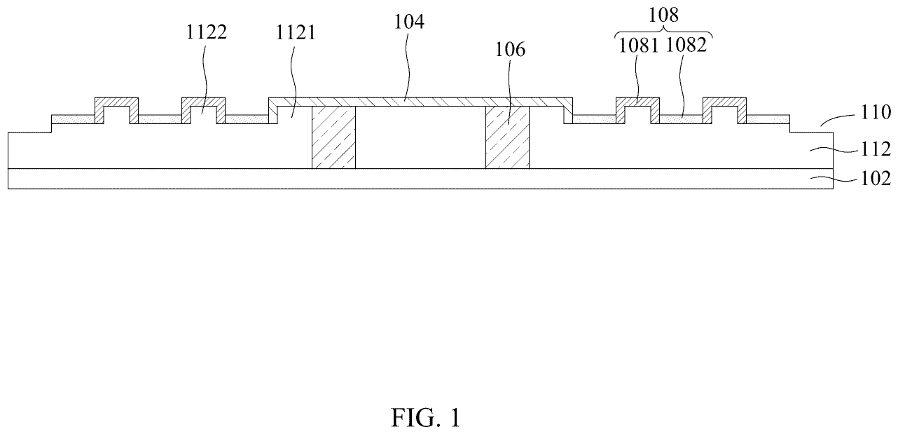

Refer to FIG. 1. FIG. 1 illustrates a schematic cross-sectional view of a semiconductor device 100. The semiconductor device 100 includes a substrate 102, a dielectric layer 112 over the substrate 102, a conductive feature 104 over the dielectric layer 112 and is coupled to an interconnect embedded in the substrate 102 by a connecting via 106, and a plurality of dummy structures 108 over the dielectric layer 112 and surrounding the conductive feature 104 in accordance with some embodiments of the present disclosure. In some embodiments, a top surface of the conductive feature 104 is separate from top surfaces of the plurality of dummy structures 108. In some embodiments, the plurality of dummy structures 108 are electrically connected to the conductive feature 104. In some embodiments, the dielectric layer 112 of the semiconductor device 100 may include a concave portion 110 surrounding the plurality of dummy structures 108 and the conductive feature 104. In some embodiments, the concave portion 110 has a bottom in a level vertically lower than that of the top surfaces of the plurality of dummy structures 108.

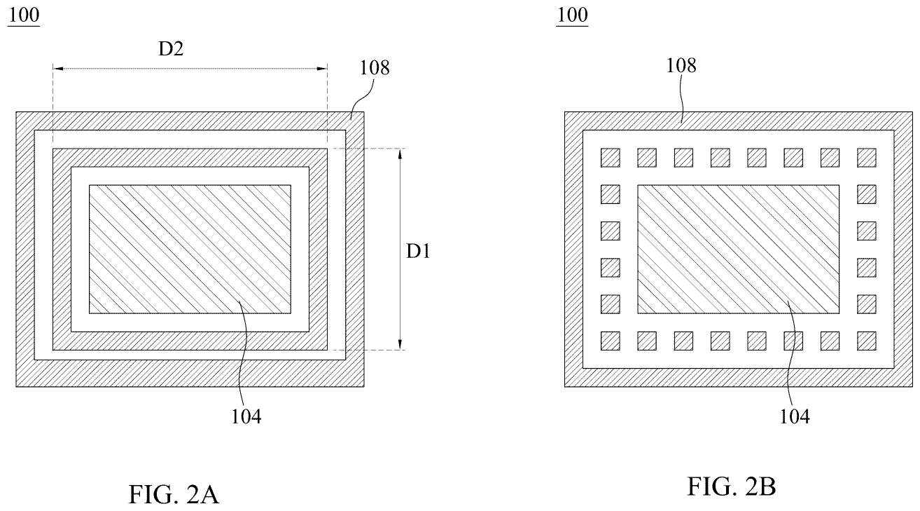

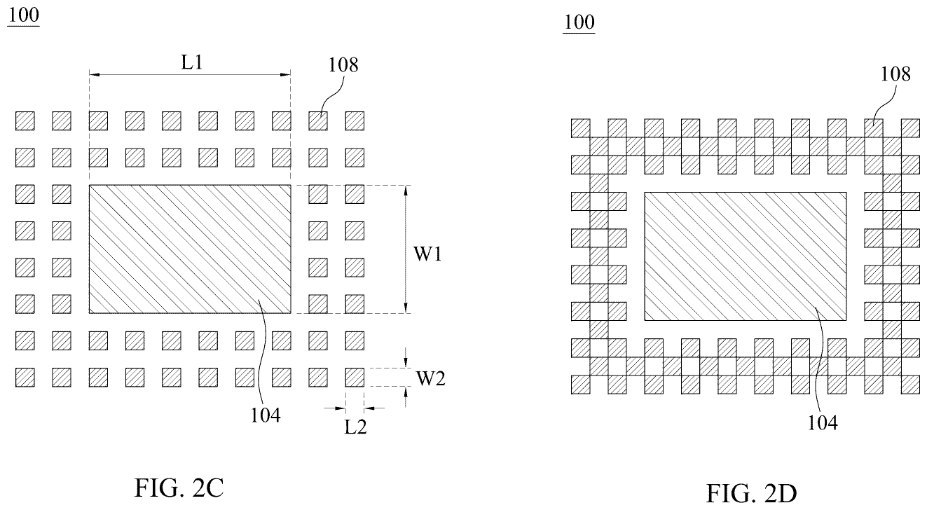

In some embodiments, the connecting via 106 is embedded in the dielectric layer 112. In some embodiments, the dielectric layer 112 may include a plurality of dielectric protrusions, which include a first protrusion 1121 and a plurality of second protrusions 1122. In some embodiments, the conductive feature 104 cover one of the plurality of dielectric protrusions. In some embodiments, the conductive feature 104 covers a top surface of the first protrusion 1121. In some embodiments, the conductive feature 104 covers a sidewall of the first protrusion 1121. In some embodiments, each of the dummy structures 108 cover one of the second protrusions 1122. In some embodiments, a top surface of the first protrusion 1121 may be of an area greater than that of a top surface of one of the plurality of second protrusions 1122. The top surface of the first protrusion 1121 is coplanar or level with the top surfaces of the second protrusions 1122. In some embodiments, a length L2 of each of the plurality of second protrusions 1122, as shown in FIG. 2C, may be less a length L1 of the first protrusion 1121. In some embodiments, as shown in FIG. 2A, a distance D2 of the top surface of one of the plurality of second protrusions 1122 may be greater than the length L1 of the first protrusion 1121. In some embodiments, a width W2 of each of the plurality of second protrusions 1122, as shown in FIG. 2C, may be less a width W1 of the first protrusion 1121. In some embodiments, as shown in FIG. 2A, a distance D1 of the top surface of one of the plurality of second protrusions 1122, may be greater the width W1 of the first protrusion 1121. In some embodiments, the connecting via 106 is embedded in the first protrusion 1121. In some embodiments, the plurality of dummy structures 108 include a plurality of first portions 1081 and a plurality of second portions 1082 coupled to each other. The first portions 1081 and the second portions 1082 include a same material. In some embodiments, a thickness of the first portion 1081 and a thickness of the second portion 1082 are equal, but the disclosure is not limited thereto. The first portion 1081 covers the top surface and sidewalls of the second protrusions 1122. The second portion 1082 covers a top surface of the dielectric layer 112 between two adjacent first portions 1081 or between the conductive feature 104 and the adjacent first portion 1081. In other embodiments, the second portion 1082 covers a portion of the dielectric layer 112 between two adjacent second protrusions 1122. In some embodiments, the plurality of first portions 1081 and the plurality of second portions 1082 are alternately arranged over the substrate 102. In such embodiments, the first portions 1081 are connected by the second portions 1082. In some embodiments, top surfaces of the first portions 1081 and top surfaces of the second portions 1082 are in different levels. In some embodiments, the top surfaces of the second portions 1082 are in a level vertically lower than that of the top surfaces of the first portions. In some embodiments, the top surface of the conductive feature 104 is level with the top surfaces of the first portions 1081. In some embodiments, the concave portion 110 has a bottom in a level vertically lower than that of the top surfaces of the second portions 1082. In some embodiments, the bottom of the concave portion 110 is in a level vertically lower than that of the surface of the dielectric layer 112 between the two adjacent second protrusions 1122. In some embodiments, the conductive feature 104 is physically connected to at least one of the plurality of dummy structures 108. In some embodiments, a distance between top surface of the conductive feature 104 and the adjacent dummy structure 108 is at least 0.5 μm. In some embodiments, the dummy structures 108 have a width of at least 1 μm. In some embodiments, a distance between two adjacent dummy structures 108 is at least 0.5μ m.

Refer to FIGS. 2A to 2D. FIGS. 2A to 2D illustrate schematic top views of a semiconductor device in accordance with some embodiments of the present disclosure. For clarity, FIGS. 2A to 2D only show the top surface of the conductive feature 104 and top surfaces of the dummy structures 108. In some embodiments, the dummy structures 108 are arranged concentrically surrounding the conductive feature 104. As shown in FIG. 2A, in some embodiments, the top surfaces of the dummy structures 108 are arranged in the form of quadrilaterals concentrically surrounding the conductive feature 104. In some embodiments, the top surfaces of the dummy structures are arranged as two quadrilaterals concentrically surrounding the conductive feature 104. As shown in FIG. 2B, in some embodiments, the top surfaces of the dummy structures 108 concentrically surrounding the conductive feature 104 are arranged in the form of an outer quadrilateral top surface surrounding multiple inner top surfaces of the dummy structures 108. As shown in FIG. 2C, in some embodiments, the top surfaces of the dummy structures 108 are arranged in a staggered manner. As shown in FIG. 2D, in some embodiments, the top surfaces of the dummy structures 18 are arranged in a column-and-row array.

In some embodiments, the substrate 102 may include a semiconductor material. In some embodiments, the semiconductor material may include silicon. Alternatively, the substrate 102 may include other elementary semiconductor such as germanium (Ge) in accordance with some embodiments of the present disclosure. In some embodiments, the substrate 102 may additionally or alternatively include a compound semiconductor such as silicon carbide (SiC), silicon oxide, gallium nitride (GaN), gallium arsenide (GaAs), indium arsenide (InAs), indium phosphide (InP), or a combination thereof. In some embodiments, the substrate 102 may include an alloy semiconductor such as silicon germanium (SiGe), silicon germanium carbide (SiGeC), gallium arsenic phosphide (GaAsP), and gallium indium phosphide (GaInP). In some embodiments, various active elements (not shown) are formed in and/or over the semiconductor material of the substrate 102. Examples of the various active elements include transistors, diodes, other suitable elements, or a combination thereof. The transistors may be metal-oxide-semiconductor field-effect transistors (MOSFET), complementary metal oxide semiconductor (CMOS) transistors, bipolar junction transistors (BJT), high-voltage transistors, high-frequency transistors, p-channel and/or n-channel field-effect transistors (PFETs/NFETs), diodes, photodiodes, etc. In some embodiments, various passive elements (not shown) may also be formed in and/or over the semiconductor material of the substrate 102. Examples of the various passive elements include capacitors, inductors, resistors, other suitable passive elements, or a combination thereof.

The active and/or passive elements may be formed in and/or over the semiconductor material of the substrate 102 using front-end semiconductor fabrication processes, which may be referred to as front end of line (FEOL) processes. Subsequently, an interconnect (not shown) may be formed over the substrate 102 using back-end semiconductor fabrication processes, which may be referred to as back end of line (BEOL) processes. In some embodiments, the interconnect is electrically connected to the connecting via 106 embedded in the dielectric layer 112.

In some embodiments, the conductive feature 104 may include a conductive material such as metal. In some embodiments, the metal may include titanium, copper, aluminum, tin, or a combination thereof. In some embodiments, the dummy structures 108 may include a conductive material such as metal. In some embodiments, the dummy structures 108 may include titanium, copper, aluminum, tin, or a combination thereof. In some embodiments, the conductive feature 104 and the dummy structures 108 may include the same conductive material.

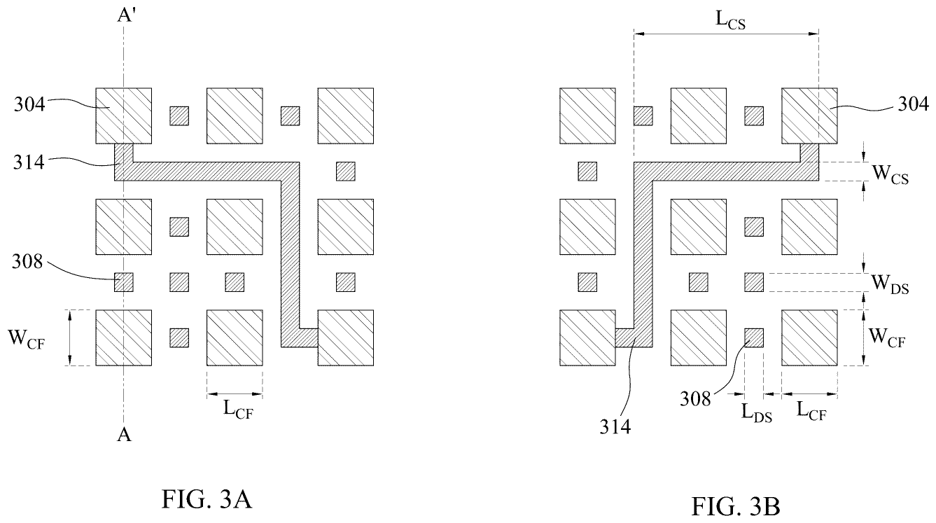

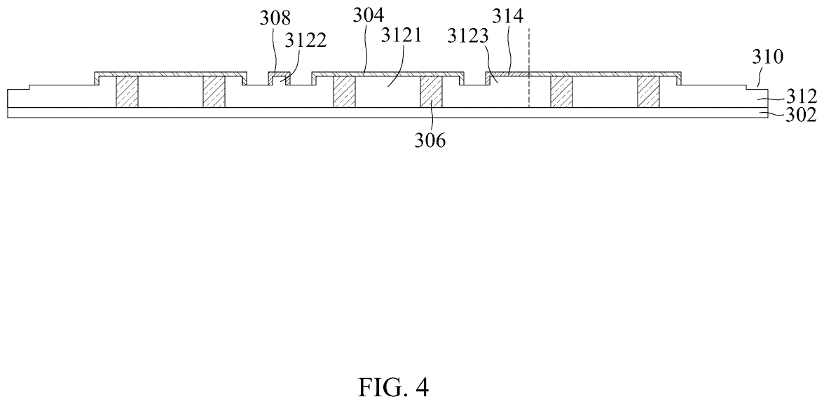

Refer to FIGS. 3A and 3B4 and 4. FIGS. 3A and 3B illustrate schematic top-views of a semiconductor device 300 in accordance with some embodiments of the present disclosure. FIG. 4 illustrates a schematic cross-sectional view of a semiconductor device 300 as shown in FIG. 3A by line A-A′ in accordance with some embodiments of the present disclosure. The semiconductor device 300 includes a substrate 302, a dielectric layer 312 over the substrate 302, a plurality of conductive features 304, a plurality of dummy structures 308, and at least one connection segment 314. In some embodiments, the dielectric layer 312 includes a plurality of first protrusions 3121, a plurality of second protrusions 3122, and at least one third protrusion 3123. In some embodiments, the plurality of conductive features 304 are formed over the plurality of first protrusions 3121 of the dielectric layer 312. In some embodiments, the plurality of dummy structures 308 are formed over the plurality of second protrusions 3122 of the dielectric layer 312. In some embodiments, the at least one connection segment 314 is formed over the at least one third protrusion 3123 of the dielectric layer 312. In some embodiments, the at least one connection segment 314 is electrically connected to at least two of the plurality of conductive features 304. In some embodiments, the plurality of dummy structures 308 are electrically disconnected from the plurality of the conductive features 304. In some embodiments, the plurality of dummy structures 308 are electrically disconnected from the connection segment 314.

In some embodiments, each of the first protrusions 3121, the second protrusions 3122 and the at least one third protrusion 3123 of the dielectric layer 312 have a top surface and sidewall(s). In some embodiments, the plurality of conductive features 304 cover top surfaces of the first protrusions 3121 of the dielectric layer 312. In some embodiments, the plurality of conductive features 304 cover sidewalls of the plurality of first protrusions 3121 of the dielectric layer 312. In some embodiments, the plurality of dummy structures 308 cover top surfaces of the plurality of second protrusions 3122 of the dielectric layer 312. In some embodiments, the plurality of dummy structures 308 cover sidewalls of the plurality of second protrusions 3122 of the dielectric layer 312. In some embodiments, the at least one connection segment 314 covers a sidewall of the at least third protrusion 3123. In some embodiments, top surfaces of the plurality of conductive features 304 are level with top surfaces of the plurality of dummy structures 308 and a top surface of the at least one connection segment 314. In some embodiments, the connection segment 314 may have a width W_{CS} same as a width W_{DS} of the dummy structures 308 as shown in FIG. 3B. In some embodiments, the connection segment 314 may have a length Lcs greater than a length L_{CF} of one of the plurality of conductive features 304 as shown in FIG. 3B. In some embodiments, the connection segment 314 may have a width W_{CS} less than a width W_{CF} of one of the plurality of conductive features 304 as shown in FIG. 3B. In some embodiments, the conductive feature 304 may have a length L_{CR} greater than a length Lcs of one of the plurality of conductive features 304 as shown in FIG. 3B. In some embodiments, the conductive feature 304 may have a width W_{CF} greater than a width W_{CS} of the at least one connection segment 314 304 as shown in FIG. 3B. In some embodiments, the plurality of the conductive features 304 are electrically connected to a connecting via 306 embedded in the dielectric layer 312. In some embodiments, the semiconductor device 300 further includes a concave portion 310 surrounding the plurality of conductive features 304, the plurality of dummy structures 308, and the at least one connection segment 314. In some embodiments, a top surface of the dielectric layer 312 is exposed between a conductive feature 304 and adjacent dummy structure 308. In some embodiments, the concave portion 310 has a bottom in a level vertically lower than top surfaces of the plurality of conductive features 304, the plurality of dummy structures 308 and the at least one connection segment 314. In some embodiments, the concave portion 310 has a bottom in a level vertically lower than the top surface of the dielectric layer 312 exposed between one of the plurality of conductive feature 304 and adjacent dummy structure 308.

The conductive features 304 and the plurality of dummy structures 308 may include materials similar to those of the conductive features 104 and the plurality of dummy structures 108 as described above, and therefore details of the materials are omitted for brevity. As for the at least one connection segment 314, it may include a material similar to those of the conductive features 304 and the plurality of dummy structures 308.

Refer to FIGS. 3A and 3B again. FIGS. 3A and 3B show the top surfaces of the conductive features 304, the top surfaces of the dummy structures 308 and the top surfaces of the at least one connection segment. In some embodiments, as shown in FIG. 3A, at least one dummy structure 308 or a portion of the at least one connection segment 314 is arranged between two adjacent conductive features 304. In some embodiments, as shown in FIG. 3B, no dummy structure 308 or any portion of the at least one connection segment 314 is arranged between two adjacent conductive features 304. The arrangement of the at least one connection segment 314, the plurality of conductive features 304 and the plurality of dummy structures 308 depend on the need for pick force between the pick head and the semiconductor device. In some embodiments, top surface of the at least one connection segment is physically connected to top surfaces of at least two of the plurality of conductive features 304. In some embodiments, the semiconductor device 300 may further include at least one dummy structure 308 arranged between two adjacent dummy structures.

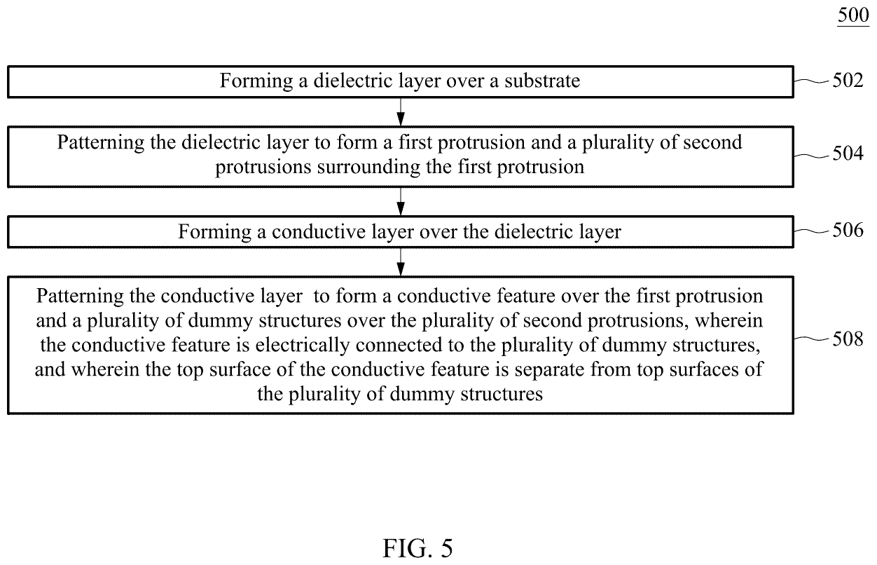

Refer to FIG. 5. FIG. 5 illustrates a flowchart of a method for forming a semiconductor device 100 according to aspects of the present disclosure. The method 500 includes a number of operations and will be further described according to one or more embodiments. It should be noted that the operations of the method 500 may be rearranged or otherwise modified within the scope of the various aspects. It should be further noted that additional processes may be provided before, during, and after the method 500, and that some other processes may just be briefly described herein. Thus, other implementations are possible within the scope of the various aspects described herein.

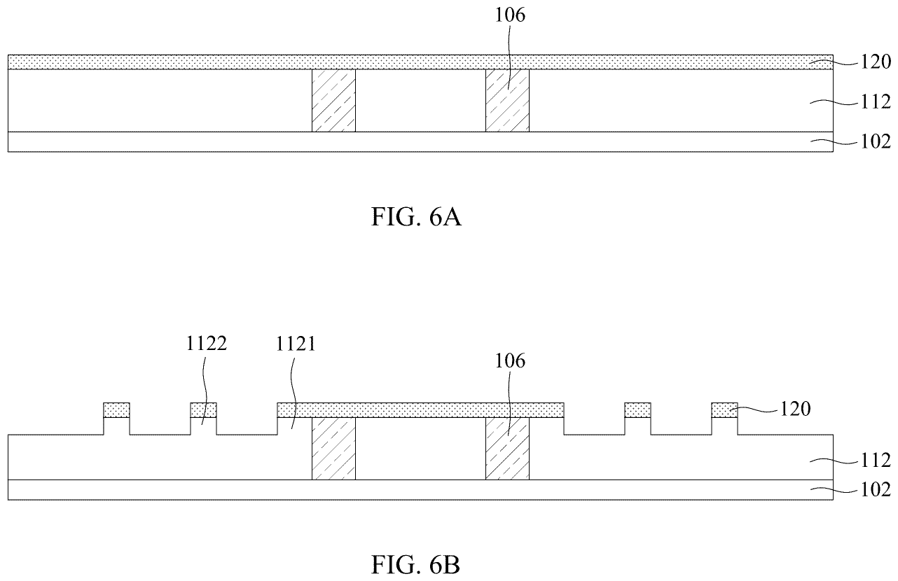

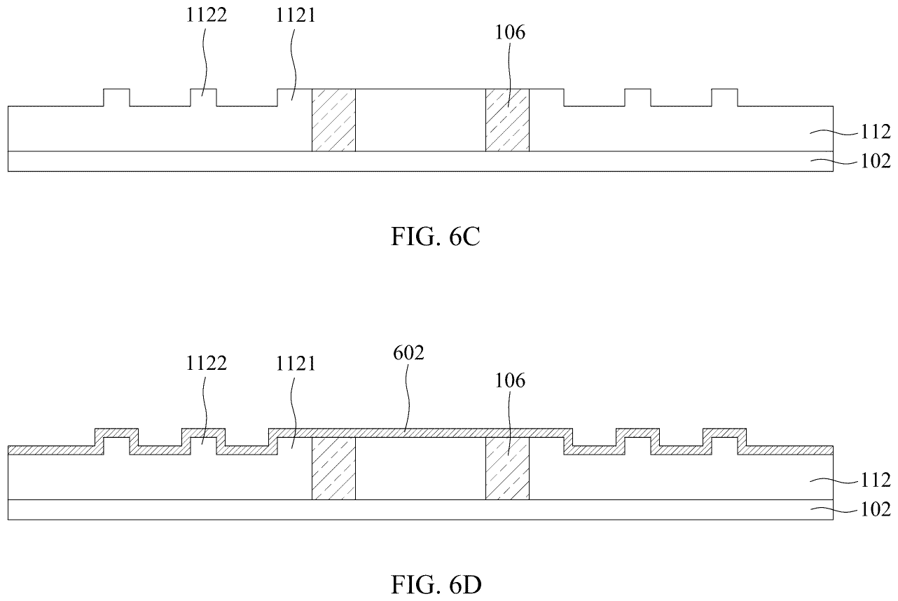

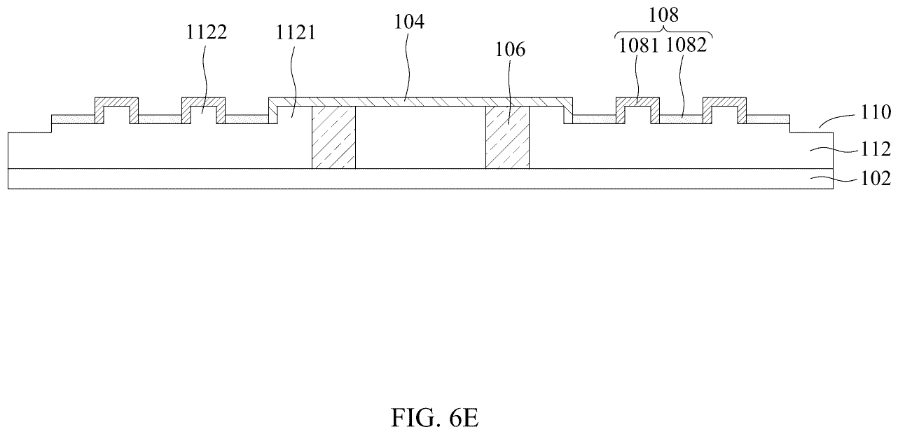

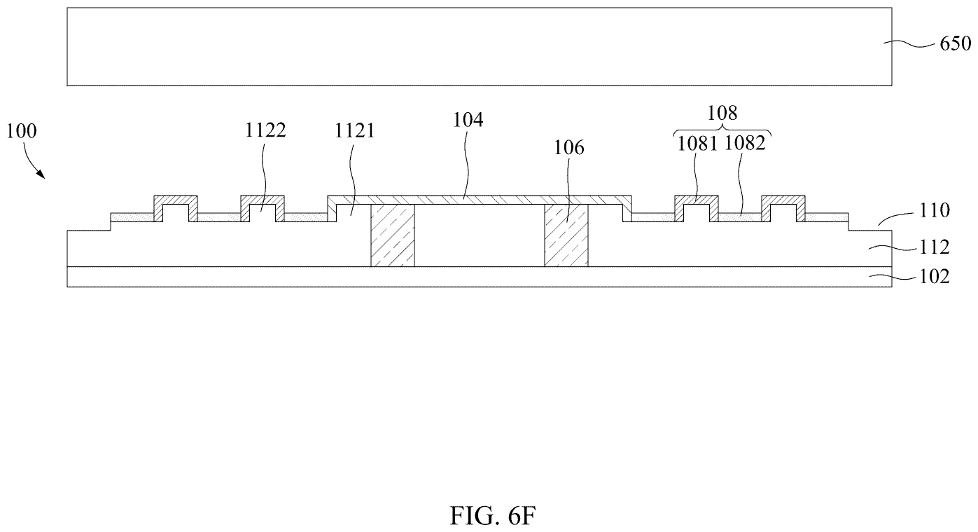

The method 500 begins with operation 502 in which a dielectric layer 112 is formed over a substrate 102. In some embodiments, the dielectric layer 112 may be formed using chemical vapor deposition (CVD), physical vapor deposition (PVD) or atomic layer deposition (ALD), but the disclosure is not limited thereto In some embodiments, an connecting via 106 is embedded in the dielectric layer 112. In some embodiments, the connecting via 106 is formed by sputtering, chemical solution deposition (CSD), pulsed laser deposition (PLD), CVD, PVD or ALD, but the disclosure is not limited thereto. Referring to FIG. 6A, in some embodiments, an initial conductive layer 120 is formed on the dielectric layer 112. In some embodiments, the initial conductive layer 120 may include a metal, such as aluminum or tin.

Referring to FIG. 6B, in some embodiments, the method 500 proceeds with operation 504, in which the dielectric layer 112 is patterned to form a first protrusion 1121 and a plurality of second protrusions 1122 surrounding the first protrusion 1121. In some embodiments, after the initial conductive layer 120 is formed, a photolithographic masking process may be performed to the initial conductive layer 120 to define a pattern of initial conductive layer 120 and the underlying dielectric layer 112. In some embodiments, an etching process may be performed to the initial conductive layer 120 and the underlying dielectric layer 112 to remove a portion of the initial conductive layer 120 and the underlying dielectric layer 112 to form a patterned initial conductive layer 120 and a plurality of dielectric protrusions of the dielectric layer 112, wherein the plurality of dielectric protrusions include a first protrusion 1121 and a plurality of second protrusions 1122 surrounding the first protrusion 1121. In some embodiments, the etching process may include a wet etching process and a dry etching process, or a combination thereof. In some embodiments, a testing process is conducted to the semiconductor device 100 via the patterned initial conducive layer 120 to determine the processability of the semiconductor device 100. In some embodiment, the testing process is conducted to a pattern other than the patterned initial conducive layer 120 formed on the first protrusion 1121 and the plurality of second protrusions 1122, which is formed at the same time the patterned initial conducive layer 120 is formed.

Referring to FIG. 6C, in some embodiments, after the testing process is conducted, a planarization operation such as a chemical-mechanical polishing (CMP) may be performed to remove the patterned initial conductive layer 120 from the semiconductor device 100 because the patterned initial conducive layer 120 may be damaged during the testing process. In some embodiments, after the testing process is conducted, a planarization operation such as a CMP may be performed to remove the patterned initial conductive layer 120 along with the pattern other than the patterned initial conductive layer 120 formed on the first protrusion and the plurality of second protrusions from the semiconductor device 100 because the pattern is damaged after the testing process is conducted. As shown in FIG. 6C, among the dielectric protrusions, the first protrusion 1121 is the one in which the connecting via 106 is embedded. In some comparative approaches, when a planarization process is performed to an isolated first protrusion 1121 in absence of the surrounding second protrusions 1122, dishing effect and surface roughness are generally found on a top surface of such first protrusion. In some embodiments, in contrast with the comparative approaches, when a planarization process is performed to a first protrusion 1121 surrounded by the plurality of second protrusions 1122, the dishing effect and surface roughness of the first protrusion 1121 after the planarization operation are reduced.

Referring to FIG. 6D, in some embodiments, the method 500 proceeds with operation 506, in which a conductive layer 602 is formed over the dielectric layer 112. In some embodiments, the conductive layer 602 may include a conductive material such as a metal. In some embodiments, the conductive layer 602 may include a conductive material different from the initial conductive layer 120. In some embodiments, the conductive layer 602 may include titanium or copper. In some embodiments, the conductive layer 602 may be formed using sputtering, chemical solution deposition (CSD), pulsed laser deposition (PLD), CVD, PVD or ALD, but the disclosure is not limited thereto.

Referring to FIG. 6E, in some embodiments, the method 500 proceeds with operation 508, in which the conductive layer 602 is patterned to form a conductive feature 104 over the first protrusion 1121, and a plurality of dummy structures 108 are formed over the plurality of second protrusions 1122. In some embodiments, a photolithographic masking process may be performed to the conductive layer 602 to define a pattern of the conductive layer 602. In some embodiments, an etching process may be performed to the conductive layer 602 to form the conductive feature 104 over the first protrusion 1121, and the plurality of dummy structures 108 over the plurality of second protrusions 1122. In some embodiments, the etching process may include a wet etching process and a dry etching process, or a combination thereof. In some embodiments, the conductive feature 104 is electrically connected to the plurality of dummy structures 108. In some embodiments, a top surface of the conductive feature 104 is separate from top surfaces of the plurality of dummy structures 108. In some embodiments, the plurality of dummy structures 108 may include at least two dummy structures 108 concentrically surrounding the conductive feature 104, and top surfaces of the at least two dummy structures 108 are disconnected with each other. In some embodiments, a top surface of the conductive feature 104 is level with top surfaces of the plurality of dummy structures 108.

Referring to FIG. 6E, in some embodiments, the method 500 may include a further operation, in which a portion of the dielectric layer 112 is removed to form a concave region 110 surrounding the conductive feature 104 and the plurality of dummy structures 108. In some embodiments, an etching process may be performed to the dielectric layer 112 to define the concave region 110. In some embodiments, the etching process may include a wet etching process and a dry etching process, or a combination thereof.

Referring to FIG. 6F, in some embodiments, when a pick head (“multi-pick array”) 650 contacts the semiconductor device 100, the pick head 650 not only contacts the top surface of the conductive feature 104, but also contacts the top surfaces of the dummy structures 108 surrounding the top surface of the conductive feature 104. The overall contact area of the semiconductor device 100 with the pick head 650 is increased and thus the pick force between the pick head 650 and the semiconductor device 100 is increased.

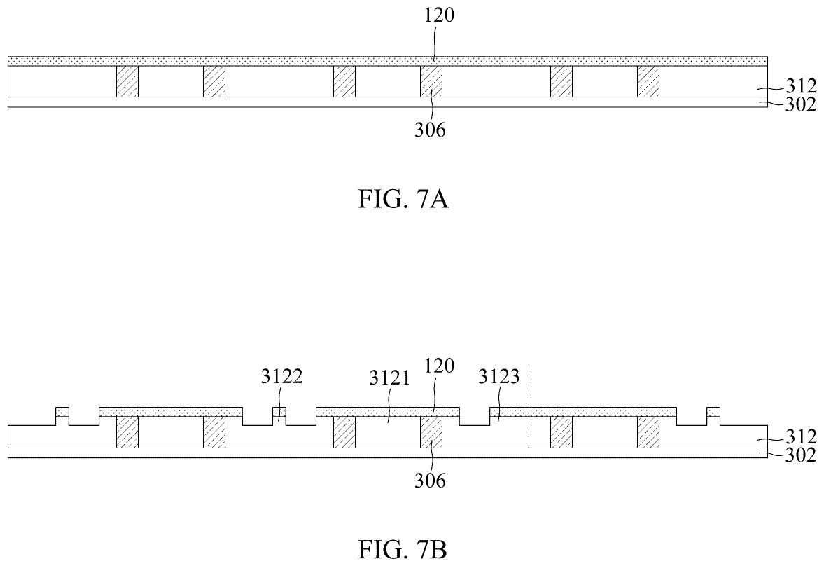

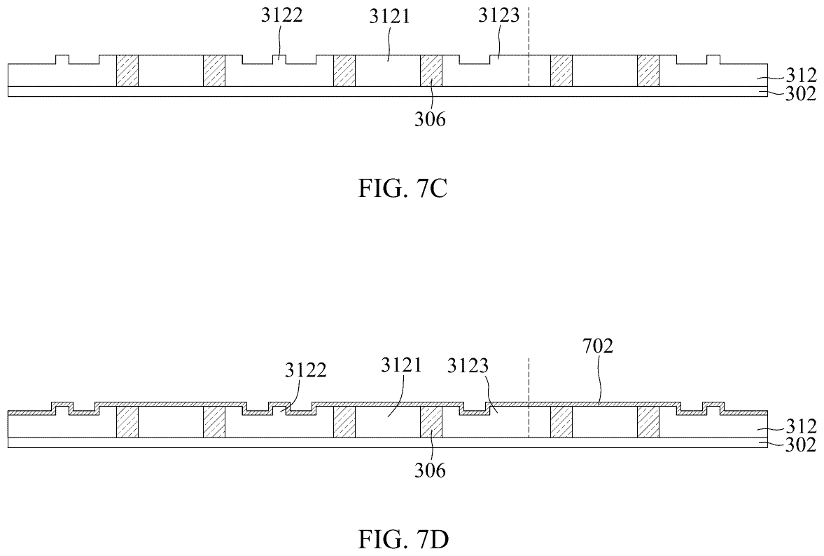

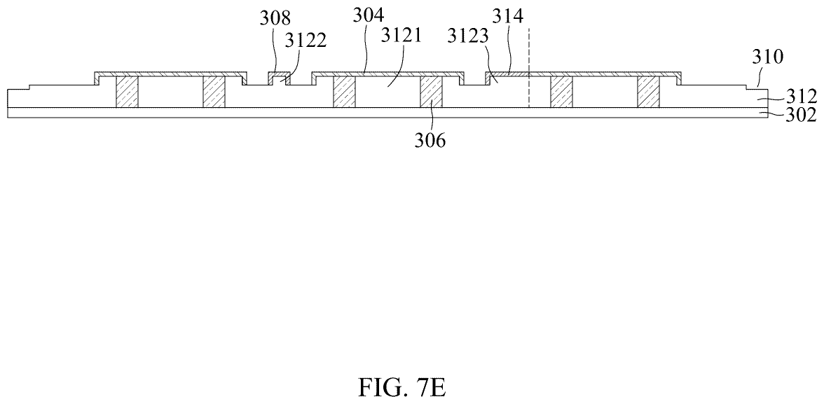

FIGS. 7A to 7E illustrate schematic cross-sectional views of a semiconductor device 300 at various stages of fabrication in accordance with some embodiments of the present disclosure.

Referring to FIG. 7A, in some embodiments, in which a dielectric layer 312 is formed over a substrate 302. In some embodiments, the dielectric layer 312 may be formed using chemical vapor deposition (CVD), physical vapor deposition (PVD) or atomic layer deposition (ALD), but the disclosure is not limited thereto In some embodiments, a plurality of connecting vias 306 are formed within the dielectric layer 312. In some embodiments, the connecting vias 306 are formed by sputtering, chemical solution deposition (CSD), pulsed laser deposition (PLD), CVD, PVD or ALD, but the disclosure is not limited thereto. Referring to FIG. 7A, in some embodiments, an initial conductive layer 120 is formed on the dielectric layer 312. In some embodiments, the initial conductive layer 120 may include a metal, such as aluminum or tin.

Referring to FIG. 7B, in some embodiments, the dielectric layer 312 is patterned to form a plurality of first protrusions 3121 and a plurality of second protrusions 3122 surrounding the plurality of first protrusions 3121. In some embodiments, after the initial conductive layer 120 is formed, a photolithographic masking process may be performed to the initial conductive layer 120 to define a pattern of initial conductive layer 120 and the underlying dielectric layer 312. In some embodiments, an etching process may be performed to the initial conductive layer 120 and the underlying dielectric layer 312 to remove a portion of the initial conductive layer 120 and the underlying dielectric layer 312 to form a patterned initial conductive layer 120 and a plurality of dielectric protrusions of the dielectric layer 312, wherein the plurality of dielectric protrusions include a plurality of first protrusions 3121, a plurality of second protrusions 3122 and at least one third protrusion 3133. In some embodiments, the etching process may include a wet etching process and a dry etching process, or a combination thereof. In some embodiments, a testing process is conducted to the semiconductor device 300 via the patterned initial conducive layer 120 to determine the processability of the semiconductor device 300. In some embodiment, the testing process is conducted to a pattern other than the patterned initial conducive layer 120 formed on the plurality of first protrusions 3121, the plurality of second protrusions 3122 and the at least one third protrusion 3133, which is formed at the same time the patterned initial conducive layer 120 is formed.

Referring to FIG. 7C, in some embodiments, after the testing process is conducted, a planarization operation such as a chemical-mechanical polishing (CMP) may be performed to remove the patterned initial conductive layer 120 from the semiconductor device 300 because the patterned initial conducive layer 120 is damaged after the testing process. In some embodiments, after the testing process is conducted, a planarization operation such as a CMP may be performed to remove the patterned initial conductive layer 120 along with the pattern other than the patterned initial conductive layer 120 formed on the first protrusion and the plurality of second protrusions from the semiconductor device 300 because the pattern is damaged after the testing process is conducted. As shown in FIG. 7C, among the dielectric protrusions, the plurality of first protrusions 3121 are the ones in which the connecting vias 306 are embedded. In some comparative approaches, when a planarization process is performed to isolated first protrusions 3121 in absence of the accompanying second protrusions 3122 and the accompanying at least third protrusion 3123, dishing effect and surface roughness are generally found on top surfaces of such first protrusions. In some embodiments, in contrast with the comparative approaches, when a planarization process is performed to the first protrusions 3121 accompanied by the plurality of second protrusions 1122 and the at least one third protrusion 3123, the dishing effect and surface roughness of the first protrusions 3121 after the planarization operation are reduced.

Referring to FIG. 7D, in some embodiments, a conductive layer 702 is formed over the dielectric layer 312. In some embodiments, the conductive layer 702 may include a conductive material such as a metal. In some embodiments, the conductive layer 702 may include a conductive material different from the initial conductive layer 120. In some embodiments, the conductive layer 702 may include titanium or copper. In some embodiments, the conductive layer 702 may be formed using sputtering, chemical solution deposition (CSD), pulsed laser deposition (PLD), CVD, PVD or ALD, but the disclosure is not limited thereto.

Referring to FIGS. 7E, in some embodiments, the conductive layer 702 is patterned to form a plurality of conductive features 304 over the plurality of first protrusions 3121, a plurality of dummy structures 308 are formed over the plurality of second protrusions 3122, and at least one connection segment 314 (in FIG. 3) over the at least one third protrusion. In some embodiments, a photolithographic masking process may be performed to the conductive layer 702 to define a pattern of the conductive layer 702. In some embodiments, an etching process may be performed to the conductive layer 702 to form the plurality conductive features 304 over the plurality of first protrusions 3121, the plurality of dummy structures 308 over the plurality of second protrusions 3122, and the at least one connection segment 314 over the at least one third protrusion 3123. In some embodiments, the etching process may include a wet etching process and a dry etching process, or a combination thereof. In some embodiments, the plurality of conductive features 304 are electrically disconnected to the plurality of dummy structures 308 by removing the conductive layer 702 between the plurality of conductive features 304 and the plurality of dummy structures 308 to expose the dielectric layer 312. In some embodiments, top surfaces of the plurality of conductive feature 304 are separate from top surfaces of the plurality of dummy structures 308.

Similar to FIG. 6F, in some embodiments, when a pick head (“multi-pick array”) 650 contacts the semiconductor device 300, the pick head 650 not only contacts the top surface of the plurality of conductive features 304, but also contacts the top surfaces of the dummy structures 308 and the at least one connection segment 314. The overall contact area of the semiconductor device 300 with the pick head 650 is increased and thus the pick force between the pick head 650 and the semiconductor device 300 is increased.

Accordingly, the present disclosure therefore provides a semiconductor device and a method for forming the same. In some embodiments, the semiconductor device may be a micro-LED. In some embodiments, the semiconductor device may have a contact pad pattern surrounded by a plurality of dummy structures. In some embodiments, the semiconductor device may have a plurality of contact pad patterns accompanied by a plurality of dummy structures and at least one connection segment. With the addition of the a plurality of dummy structures and, in some embodiments, with further addition of at least one connection segment, reduced dishing effect and surface roughness are found on the contact pad patterns, and the overall contact area of the semiconductor device with the pick head for the mass transfer process is increased. Therefore, the pick force between the semiconductor device and the pick head is increased, so that the die flyer effect, which refers to the semiconductor device being dropped by the pick head during the mass transfer process because of the insufficient pick force between the semiconductor device and the pick head, is thus reduced.

The present disclosure provides a semiconductor device including a pad surrounded by dummy pad patterns as seen in a plan view. Such dummy pad patterns helps to mitigate a defect issue found in manufacturing operations by reducing surface roughness of the pad pattern after CMP, and help increasing the contact area of the semiconductor device with a pick head during the pick-and-place transfer process.

In some embodiments, a semiconductor device is provided. The semiconductor device includes a substrate, a dielectric layer over the substrate, a conductive feature over the dielectric layer and is physically connected to an interconnect embedded in the dielectric layer, and a plurality of dummy structures over the dielectric layer and surrounding the conductive feature. A top surface of the conductive feature is separate from top surfaces of the dummy structures, and the plurality of dummy structures are electrically connected to the conductive feature.

In some embodiments, a semiconductor device is provided. The semiconductor device includes a substrate, a dielectric layer over the substrate, a plurality of conductive features, a plurality of dummy structures, and at least one connection segment. The dielectric layer includes a plurality of first protrusions, a plurality of second protrusion and at least one third protrusion. The plurality of conductive features are over the plurality of first protrusions of the dielectric layer. The plurality of dummy structures are over the plurality of second protrusions of the dielectric layer. The at least one connection segment is over the at least one third protrusion of the dielectric layer and is electrically connected to at least two of the plurality of the conductive features. The plurality of dummy structures are electrically disconnected from the plurality of the conductive features.

In some embodiments, a method for forming a semiconductor device is provided. The method includes following operations. A dielectric layer is formed over the substrate. The dielectric layer is patterned to form a first protrusion and a plurality of second protrusions surrounding the first protrusion. A conductive layer is formed over the dielectric layer. The conductive layer is patterned to form a conductive feature over the first protrusion and a plurality of dummy structures over the plurality of second protrusions. The conductive feature is electrically connected to the plurality of dummy structures, and a top surface of the conductive feature is separate from top surfaces of the plurality of dummy structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a dielectric layer over the substrate;
a conductive feature over the dielectric layer and physically connected to a connecting via embedded in the dielectric layer; and
a plurality of dummy structures over the dielectric layer and surrounding the conductive feature,
wherein a top surface of the conductive feature is separate from top surfaces of the dummy structures, and
wherein the plurality of dummy structures are electrically connected to the conductive feature.

2. The semiconductor device according to claim 1, wherein the dummy structures are arranged concentrically surrounding the conductive feature.

3. The semiconductor device according to claim 1, wherein the plurality of dummy structures are arranged in a staggered manner.

4. The semiconductor device according to claim 1, wherein the plurality of dummy structures are arranged in a column-and-row array.

5. The semiconductor device according to claim 1, wherein the plurality of dummy structures comprises a plurality of first portions and a plurality of second portions alternately arranged, and top surfaces of the first portions and top surfaces of the second portions are in different levels.

6. The semiconductor device according to claim 5, wherein the top surfaces of the first portions are level with the top surfaces of the conductive feature.

7. The semiconductor device according to claim 5, wherein the top surfaces of the second portion are in a level vertically lower than that of the top surfaces of the first portions.

8. The semiconductor device according to claim 5, wherein the dielectric layer comprises a plurality of dielectric protrusions, and the conductive feature and each of the plurality of first portions respectively cover one of the dielectric protrusions.

9. The semiconductor device according to claim 5, further comprising a concave portion surrounding the plurality of dummy structures and the conductive feature.

10. The semiconductor device according to claim 9, wherein the concave portion has a bottom in a level vertically lower than that of the top surfaces of the second portion.

11. A semiconductor device comprising:
a substrate;
a dielectric layer over the substrate, wherein the dielectric layer comprises a plurality of first protrusions, a plurality of second protrusions and at least one third protrusion;
a plurality of conductive features over the plurality of first protrusions of the dielectric layer;
a plurality of dummy structures over the plurality of second protrusions of the dielectric layer, and
at least one connection segment over the at least one third protrusion of the dielectric layer;
wherein the at least one connection segment is electrically connected to at least two of the plurality of the conductive features, and
wherein the plurality of dummy structures are electrically disconnected from the plurality of the conductive features.

12. The semiconductor device according to claim 11, wherein the plurality of conductive features cover sidewalls of the plurality of first protrusions.

13. The semiconductor device according to claim 11, wherein the plurality of dummy structures cover sidewalls of the plurality of second protrusions.

14. The semiconductor device according to claim 11, wherein top surfaces of the plurality of conductive features are level with top surfaces of the plurality of the dummy structures and a top surface of the at least one connection segment.

15. The semiconductor device according to claim 11, wherein the plurality of the conductive features are electrically connected to an interconnect in the substrate.

16. The semiconductor device according to claim 11, further comprising a concave portion surrounding the plurality of conductive features, the plurality of dummy structures and the at least one conductive segment.

17. A method for preparing a semiconductor device, comprising:
forming a dielectric layer over a substrate;
patterning the dielectric layer to form a first protrusion and a plurality of second protrusions surrounding the first protrusion;
forming a conductive layer over the dielectric layer;
patterning the conductive layer to form a conductive feature over the first protrusion and a plurality of dummy structures over the plurality of second protrusions,
wherein the conductive feature is electrically connected to the plurality of dummy structures, and
wherein a top surface of the conductive feature is separate from top surfaces of the plurality of dummy structures.

18. The method of claim 17, further comprising removing a portion of the dielectric layer to form a concave region surrounding the conductive feature and the plurality of dummy structures.

19. The method of claim 17, wherein the plurality of second protrusions comprises at least two second protrusions concentrically surrounding the first protrusion, and top surfaces of the at least two second protrusions are disconnected with each other.

20. The method of claim 17, wherein a top surface of the conductive feature is level with top surfaces of the plurality of dummy structures.
